(19) United States
(12) Patent Application Publication
(10) Pub. No.: US 2026/0150193 A1
(43) Pub. Date: May 28, 2026

(54) PRINTED CIRCUIT BOARD

(71) Applicant: SAMSUNG ELECTRO-MECHANICS CO., LTD., Suwon-si (KR)

(72) Inventors: Sang Hoon KIM, Suwon-si (KR); Chan Hoon KO, Suwon-si (KR); Ki Eun CHO, Suwon-si (KR); Ji Ho YOON, Suwon-si (KR); Min Jae SEONG, Suwon-si (KR)

(73) Assignee: SAMSUNG ELECTRO-MECHANICS CO., LTD., Suwon-si (KR)

(21) Appl. No.: 19/260,030

(22) Filed: Jul. 3, 2025

(30) Foreign Application Priority Data
Nov. 22, 2024 (KR) 10-2024-0168856

(51) Int. Cl. H05K 1/11; H05K 1/03; H05K 1/09

(52) U.S. Cl. CPC H05K 1/111; H05K 1/0373; H05K 1/09; H05K 1/115

(57) ABSTRACT

A printed circuit board includes an insulating layer, a conductive pad buried in an upper side of the insulating layer, the conductive pad having an upper surface having at least a portion exposed from an upper surface of the insulating layer, a first conductive bump disposed on the upper surface of the conductive pad, a passivation layer disposed on the upper surface of the insulating layer, the passivation layer covering a portion of the upper surface of the conductive pad and a portion of a side surface of the first conductive bump, and a second conductive bump disposed on an upper surface of the passivation layer, the second conductive bump covering another portion of the side surface of the first conductive bump and an upper surface of the first conductive bump.

### CROSS-REFERENCE TO RELATED APPLICATION(S)

This application claims benefit of priority to Korean Patent Application No. 10-2024-0168856 filed on Nov. 22, 2024 in the Korean Intellectual Property Office, the disclosure of which is incorporated herein by reference in its entirety.

### TECHNICAL FIELD

The present disclosure relates to a printed circuit board.

The pitch of bumps on a substrate connected to a flip-chip die has been continuously decreasing. In fine-pitch configurations, risks such as solder ball mounting issues and bonding reliability degradation may arise. Therefore, the application of conductive bumps is being considered. However, conductive bumps may have limitations in terms of height, as well as in width resolution. In addition, the size of the conductive bump may be affected by the size of the conductive pad. When the bump is formed below a certain size due to the influence of the conductive pad, bonding reliability with a die may be weakened. In addition, as the pitch decreases, such risks may increase.

### SUMMARY

An aspect of the present disclosure is to provide a printed circuit board capable of increasing a height of a conductive bump and increasing a size of the conductive bump.

A first conductive bump, connected to a conductive pad formed on an insulating layer, may be formed on the conductive pad. A passivation layer having a height, lower than that of the first conductive bump, may be formed on the insulating layer, such that an upper end of the first conductive bump may protrude onto the passivation layer. A second conductive bump, covering the protruding upper end of the first conductive bump, may be formed on the passivation layer. The conductive pad may be buried in the insulating layer. The insulating layer may include a photosensitive insulating material.

According to an aspect of the present disclosure, there is provided a printed circuit board includes an insulating layer, a conductive pad buried in an upper side of the insulating layer, the conductive pad having an upper surface having at least a portion exposed from an upper surface of the insulating layer, a first conductive bump disposed on the upper surface of the conductive pad, a passivation layer disposed on the upper surface of the insulating layer, the passivation layer covering a portion of the upper surface of the conductive pad and a portion of a side surface of the first conductive bump, and a second conductive bump disposed on an upper surface of the passivation layer, the second conductive bump covering another portion of the side surface of the first conductive bump and an upper surface of the first conductive bump.

According to another aspect of the present disclosure, there is provided a printed circuit board including a conductive pad, a first conductive bump connected to an upper surface of the conductive pad, a second conductive bump connected to an upper end of the first conductive bump, an insulating layer in contact with at least a portion of the conductive pad, the insulating layer spaced apart from the first and second conductive bumps, the insulating layer including a photosensitive insulating material, and a passivation layer disposed on an upper surface of the insulating layer, the passivation layer in contact with at least a portion of each of the conductive pad and the first and second conductive bumps. The upper end of the first conductive bump to which the second conductive bump is connected may protrude onto an upper surface of the passivation layer.

According to example embodiments of the present disclosure, a printed circuit board may increase a height of a conductive bump and increase a size of the conductive bump.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example electronic device system;

FIG. 2 is a schematic perspective view of an example of an electronic device;

FIG. 3 is a schematic cross-sectional view of an example of a printed circuit board;

FIG. 4 is a schematic process diagram of an example of a method of manufacturing the printed circuit board of FIG. 3;

FIG. 5 is a schematic cross-sectional view of another example of a printed circuit board;

FIG. 6 is a schematic cross-sectional view of another example of a printed circuit board;

FIG. 7 is a schematic cross-sectional view of another example of a printed circuit board;

FIG. 8 is a schematic cross-sectional view of another example of a printed circuit board; and

FIG. 9 is a schematic planar view of a top view of the printed circuit board of FIG. 8.

### DETAILED DESCRIPTION

Hereinafter, example embodiments of the present disclosure are described with reference to the accompanying drawings. The shapes and sizes of components in the drawings may be exaggerated or reduced for clearer description.

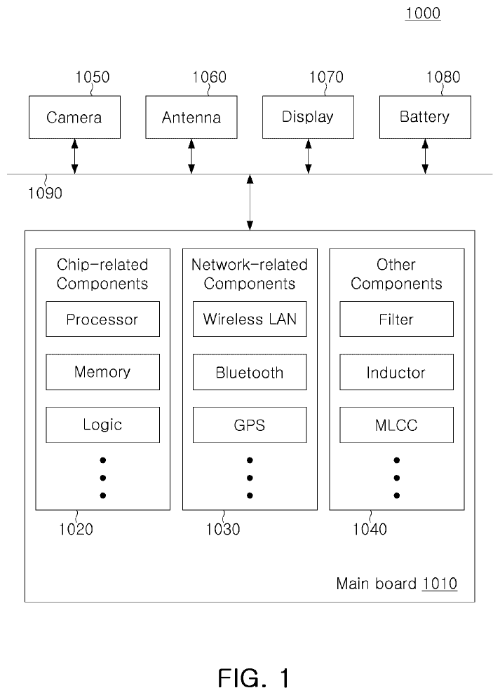

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

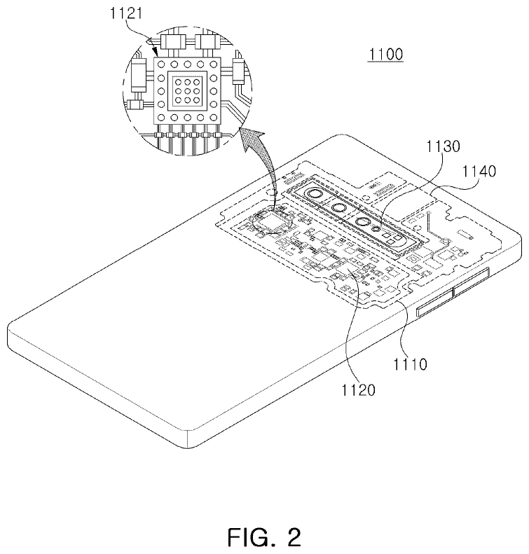

FIG. 2 is a schematic perspective view of an example of an electronic device.

Referring to the drawings, an electronic device may be, for example, a smartphone 1100. The motherboard 1110 may be accommodated in the smartphone 1100, and various electronic components 1120 may be physically and/or electrically connected to the motherboard 1110. In addition, other electronic components that may be or may not be physically and/or electrically connected to the motherboard 1110 may be accommodated therein, such as a camera module 1130 and/or a speaker 1140. A portion of the electronic components 1120 may be the chip-related components described above, for example, a component package 1121, but the present disclosure is not limited thereto. The component package 1121 may be in the form of a printed circuit board on which electronic components including active components and/or passive components are surface-mounted. The electronic device is not limited to the smartphone 1100, and may be other electronic devices, as described above.

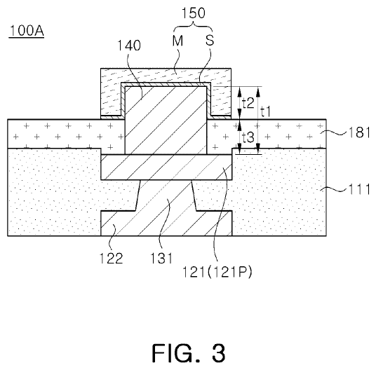

FIG. 3 is a schematic cross-sectional view of an example of a printed circuit board.

Referring to the drawings, a printed circuit board 100A according to some example embodiments of the present disclosure may include an insulating layer 111, a first wiring layer 121 embedded in an upper side of the insulating layer 111, the first wiring layer 121 including a conductive pad 121P, a second wiring layer 122 embedded in a lower side of the insulating layer 111, a via layer 131 disposed between the first wiring layer 121 and the second wiring layer 122, the via layer 131 connecting the first and second wiring layers 121 and 122 to each other, a first conductive bump 140 disposed on an upper surface of the conductive pad 121P, a passivation layer 181 disposed on an upper surface of the insulating layer 111, the passivation layer 181 covering a portion of the upper surface of the conductive pad 121P and a portion of a side surface of the first conductive bump 140, and a second conductive bump 150 disposed on an upper surface of the passivation layer 181, the second conductive bump 150 covering another portion of the side surface of the first conductive bump 140 and an upper surface of the first conductive bump 140. The first conductive bump 140 may be connected to the upper surface of the conductive pad 121P. An upper end of the first conductive bump 140 may protrude onto the upper surface of the passivation layer 181, and the second conductive bump 150 may be connected to the protruding upper end of the first conductive bump 140. The insulating layer 111 may be in contact with at least a portion of the conductive pad 121P, and may be spaced apart from the first and second conductive bumps 140 and 150. The passivation layer 181 may be in contact with at least a portion of each of the conductive pad 121P, the first conductive bump 140, and the second conductive bump 150.

As described above, in the printed circuit board 100A according to some example embodiments, the first conductive bump 140 may be disposed on the conductive pad 121P, the passivation layer 181 may be disposed on the insulating layer 111 at a height lower than the first conductive bump 140, and the second conductive bump 150 may cover a portion of the first conductive bump 140 protruding from the passivation layer 181. The conductive pad 121P, the passivation layer 181, and the first and second conductive bumps 140 and 150 having such a structure described above may be suitably applied to mounting of a high-performance die requiring high-density input/output terminals. For example, overall heights of the first and second conductive bumps 140 and 150 may be increased, which may facilitate securing a standoff height between a die and a substrate, thereby enabling stable connection with a die bump and underfill formation. In addition, a size of the second conductive bump 150 may be increased independently of a design rule of the conductive pad 121P, thereby improving connection strength with the die.

The first wiring layer 121 may be a buried trace substrate (ETS) pattern layer. For example, the first wiring layer 121 may be buried in the upper side of the insulating layer 111, and at least a portion of an upper surface of the first wiring layer 121 may be exposed from at least a portion of the upper surface of the insulating layer 111. In addition, the conductive pad 121P, included in the first wiring layer 121, may also be buried in the upper side of the insulating layer 111, and at least a portion of the upper surface of the conductive pad 121P may be exposed from the upper surface of the insulating layer 111. In this case, a coreless structure may be easily implemented. Accordingly, it may be more advantageous for forming high-density wiring. In addition, an overall thickness of the substrate may be reduced. The upper surface of the conductive pad 121P may be recessed below the upper surface of the insulating layer 111. For example, a recess step portion may be formed, and the passivation layer 181 may fill at least a portion of the recessed space of the recess step portion to improve adhesion, thereby further enhancing reliability.

The insulating layer 111 may include a photosensitive insulating material. For example, the insulating layer 111 may include a photoimageable dielectric (PID). In this case, the coreless structure may be more easily implemented, as described above. In addition, a high-density wiring may be more easily formed in the insulating layer 111. In addition, the thickness of the substrate may be further reduced. The photosensitive insulating material may include a liquid-type insulating material or a film-type insulating material. In addition, the photosensitive insulating material may include an epoxy-based photosensitive polymer or an acryl-based photosensitive polymer, and may further include a filler such as silica and other additives, as necessary.

When a thickness from the upper surface of the conductive pad 121P to the upper surface of the first conductive bump 140 is denoted by t1, and a thickness from the upper surface of the passivation layer 181 to the upper surface of the first conductive bump 140 is denoted by t2, (t1*20%)<t2<(t1*80%), (t1*30%)<t2<(t1*70%), or (t1*40%)<t2<(t1*60%) may be satisfied. In addition, when a thickness from the upper surface of the conductive pad 121P to the upper surface of the passivation layer 181 is denoted by t3, (t1*20%)<t3<(t1*80%), (t1*30%)<t3<(t1*70%), or (t1*40%)<t3<(t1*60%) may be satisfied. A protrusion height of the first conductive bump 140 may be associated with bonding reliability of the die, and a remaining thickness of the passivation layer 181 may be associated with securing insulation from the first wiring layer 121. Accordingly, when the above-described thickness ranges are satisfied, bonding reliability and insulation may be optimized. In addition, it may be more advantageous for managing a variation in the protrusion height of the first conductive bump and the remaining thickness of the passivation layer. In measuring thicknesses t1, t2, and t3, when thickness values vary slightly depending on measurement points, that is, when the thickness values are not constant, an average value of thicknesses measured at five arbitrary points with respect to each of the thicknesses t1, t2, and t3 may be used.

The second conductive bump may include a seed layer S conformally and continuously covering a portion of the upper surface of the passivation layer 181, a portion of the side surface of the first conductive bump 140, and the upper surface of the first conductive bump 140, and a pattern layer M disposed on the seed layer S. The seed layer S may be formed by electroless plating, and may include, for example, chemical copper. The pattern layer M may be formed by electrolytic plating, and may include, for example, electrolytic copper. For example, the seed layer S and the pattern layer M may be a single layer and may include copper (Cu), but the present disclosure is not limited thereto. The second conductive bump 150 may be formed through a plating process using circuit lithography, a size of the second conductive bump 150 may be easily set regardless of the conductive pad 121P. In addition, for connection with the first conductive bump, for example, bonding between copper (Cu) and copper (Cu) may be performed, thereby achieving high bonding strength.

The upper surface of the passivation layer 181 may have a surface roughness. For example, the passivation layer 181 may be etched to adjust a height thereof. In this case, the upper surface of the passivation layer 181 may have a surface roughness. A boundary between the passivation layer 181 and the second conductive bump 150 may also have a surface roughness. Accordingly, the passivation layer 181 having the surface roughness may be more effective in securing adhesion with the second conductive bump 150. In addition, it may provide a positive effect on flowability and adhesion of the underfill in a packaging operation, and adhesion of a molding material. The surface roughness of the upper surface of the passivation layer 181 may be greater than that of a lower surface of the passivation layer 181 in contact with the insulating layer 111. For example, the surface roughness of the upper surface of the passivation layer 181 may be greater than that of the lower surface of the passivation layer 181. For example, the surface roughness of the upper surface of the passivation layer 181 may be several microns to tens of microns, but the present disclosure is not limited thereto. Here, the surface roughness may refer to an average roughness (Ra).

Hereinafter, components of the printed circuit board 100A according to an example will be described in more detail with reference to the drawings.

The insulating layer 111 may include an insulating material. The insulating material may be a thermosetting resin such as an epoxy resin, a thermoplastic resin such as polyimide, or a resin in which the thermosetting resin or the thermoplastic resin is impregnated in a material mixed with an inorganic filler such as silica, or a core material such as a glass fiber, together with the inorganic filler, for example, an insulating material such as a prepreg, an Ajinomoto build-up film (ABF), a PID, and resin coated copper (RCC), but the present disclosure is not limited thereto. A PID may be preferably used, but the present disclosure is not limited thereto. The insulating layer 111 may include a plurality of layers, as necessary. The plurality of layers may include substantially the same insulating material, and the plurality of layers may not be clearly distinguished from each other, but may be distinguished from each other. In addition, the plurality of layers may include different insulating materials

Each of the first and second wiring layers 121 and 122 may include a metal. The metal may include at least one selected from the group consisting of copper (Cu), aluminum (Al), silver (Ag), tin (Sn), gold (Au), nickel (Ni), lead (Pb), titanium (Ti), and alloys thereof. For example, the first wiring layer 121 may include electric copper, formed by electrolytic plating, as a pattern layer. The first wiring layer 121 may be a buried pattern layer formed using an ETS method, and thus may not include a seed layer. The second wiring layer 122 may include chemical copper, formed by electroless plating, as a seed layer, and may include electric copper, formed by electrolytic plating based thereon, as a pattern layer. Each of the first and second wiring layers 112 and 122 may perform various functions according to a design thereof. For example, each of the first and second wiring layers 112 and 122 may include a signal transmission pattern, a power transmission pattern, a ground transmission pattern, or the like. The above-described patterns may have various pattern shapes such as a line, a trace, a plane, a pad, and a land. For example, the first wiring layer 112 may include a conductive pad 121P, as described above.

The via layer 131 may include a metal. The metal may include at least one selected from the group consisting of copper (Cu), aluminum (Al), silver (Ag), tin (Sn), gold (Au), nickel (Ni), lead (Pb), titanium (Ti), and alloys thereof. For example, the via layer 131 may include chemical copper, formed by electroless plating, as a seed layer, and may include electric copper, formed by electrolytic plating based thereon, as a pattern layer. The via layer 131 may perform various functions according to a design thereof. For example, the via layer 131 may include a signal transmission connection via, a power transmission connection via, a ground transmission connection via, or the like. A connection via, included in the via layer 131, may have a substantially tapered side surface having an upper end having a width, less than a width of a lower end thereof, in cross-section. The connection via, included in the via layer 131, may have a filled-plating via structure, but the present disclosure is not limited thereto, and may have a conformal-plating via structure. The connection via, included in the via layer 131, may be provided as a plurality of connection vias.

The first conductive bump 140 may include a metal. The metal may include at least one selected from the group consisting of copper (Cu), aluminum (Al), silver (Ag), tin (Sn), gold (Au), nickel (Ni), lead (Pb), titanium (Ti), and alloys thereof. For example, the first conductive bump 140 may include electric copper, formed by electroplating, as a pattern layer. The conductive pad 121P may be a buried pattern layer formed using the ETS method, as described above, and thus the first conductive bump 140 formed thereon may include a metal foil (for example, a copper foil) of a carrier, used in the ETS method, as a seed layer. For example, the metal foil of the carrier may remain included in the first conductive bump 140. However, the present disclosure is not limited thereto. As necessary, a seed layer may be additionally formed on the metal foil, or the seed layer may be formed by removing the metal foil. The first conductive bump 140 may perform various functions according to a design thereof. For example, the first conductive bump 140 may be connected to the second conductive bump 150 and used as a signal transmission bump, a power transmission bump, a ground transmission bump, or the like. The first conductive bump 140 may have a substantially cylindrical shape, but the present disclosure is not limited thereto. The first conductive bump 140 may have a substantially vertical side surface, but the present disclosure is not limited thereto.

The second conductive bump 150 may include a metal. The metal may include at least one selected from the group consisting of copper (Cu), aluminum (Al), silver (Ag), tin (Sn), gold (Au), nickel (Ni), lead (Pb), titanium (Ti), and alloys thereof. For example, the second conductive bump 150 may include chemical copper, formed by electroless plating, as the seed layer S, and may include electric copper, formed by electrolytic plating, as the pattern layer M. The second conductive bump 150 may perform various functions according to a design thereof. For example, the second conductive bump 150 may be connected to the first conductive bump 140 and used as a signal transmission bump, a power transmission bump, a ground transmission bump, or the like. The second conductive bump 150 may substantially cover the protruding upper end of the first conductive bump 140 in the form of a hat, but the present disclosure is not limited thereto. An edge portion of the upper surface of the second conductive bump 150 may have a substantially vertical shape, but is not limited thereto, and may have a substantially round shape.

The passivation layer 181 may include an organic insulating material. The organic insulating material may include a thermosetting resin such as an epoxy resin, a thermoplastic resin such as polyimide, or an inorganic filler and/or an organic filler together with a resin. For example, the organic insulating material may be an ABF, a PID, a solder resist (SR), or the like, but the present disclosure is not limited thereto. The passivation layer 181 may preferably include an SR, and the SR may be a liquid-type SR or a film-type SR, but the present disclosure is not limited thereto.

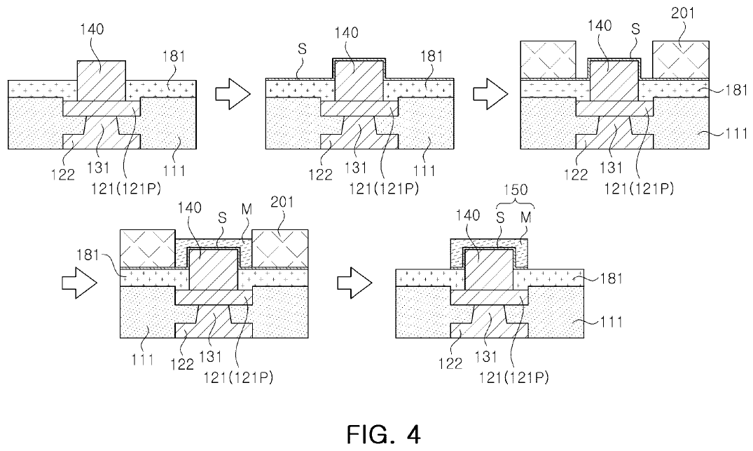

FIG. 4 is a schematic process diagram of an example of a method of manufacturing the printed circuit board of FIG. 3.

Referring to the drawings, first, a first wiring layer 121 including a conductive pad 121P, a second wiring layer 122, and a via layer 131 may be formed on an insulating layer 111 using an ETS method or the like. In addition, a first conductive bump 140 may be formed on the conductive pad 121P through a plating process using circuit lithography. In addition, after a passivation layer 181 is formed on the insulating layer 111, a height of the passivation layer 181 may be lowered through a thinning process, such that an upper end of the first conductive bump 140 may protrude. As the thinning process, wet etching or dry etching may be used. Subsequently, a seed layer S may be formed on the passivation layer 181 and the first conductive bump 140. The seed layer S may be formed by electroless plating, but the present disclosure is not limited thereto, and may be formed by sputtering, as necessary. Subsequently, a dry film resist 201 may be formed on the seed layer S. In addition, an opening pattern may be formed on the dry film resist 201 in a desired design through a photolithography process, such that the seed layer S formed on the protruding upper end of the first conductive bump 140 may be exposed. Subsequently, a pattern layer M may be formed on the seed layer S in the opening pattern of the dry film resist 201 to fill at least a portion of the opening pattern. The pattern layer M may be formed by electrolytic plating. Subsequently, the dry film resist 201 may be removed. The dry film resist 201 may be physically removed or may be chemically removed using a stripper. In addition, a remaining portion of the seed layer S, from which the dry film resist 201 has been removed, may be etched and removed. As a result, a second conductive bump 150 may be formed.

The above-described printed circuit board 100A according to an example may be manufactured through a series of processes. The contents described in connection with the above-described printed circuit board 100A according to an example may be also applied to the above-described manufacturing example in substantially the same manner.

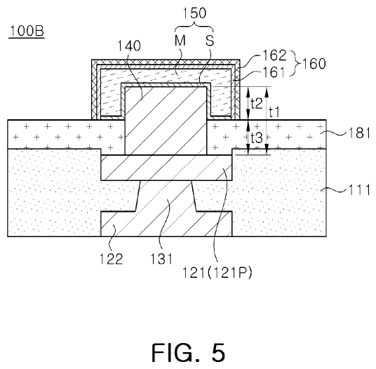

FIG. 5 is a schematic cross-sectional view of another example of a printed circuit board.

Referring to the drawings, a printed circuit board 100B according to another example embodiments of the present disclosure may further include a surface treatment layer 160 covering an upper surface and a side surface of the second conductive bump 150, as compared to the above-described printed circuit board 100A according to some example embodiments. The surface treatment layer 160 may include, for example, a plurality of layers including, in an order listed, a layer 161 including nickel (Ni) disposed on the second conductive bump 150, and a layer 162 including gold (Au) disposed on the layer 161, but the present disclosure is not limited thereto, and may be formed through various processes using various materials, as will be described below. When the surface treatment layer 160 is formed, reliability may be secured during die bonding in a packaging operation. In addition, Cu consumption may be prevented. The surface treatment layer 160 may be formed through, for example, an electroless nickel/impression gold (ENIG) process, but the present disclosure is not limited thereto, and may be formed through a process such as hot air solder leveling (HASL), immersion silver (ImAg), immersion tin (ImSn), or the like, or may be formed through an organic solderability preservative (OSP) process.

Other contents may be substantially the same as those described in connection with the above-described printed circuit board 100A according to an example. In addition, the contents described in connection with the above-described manufacturing example may also be applied to the printed circuit board 100B according to another example.

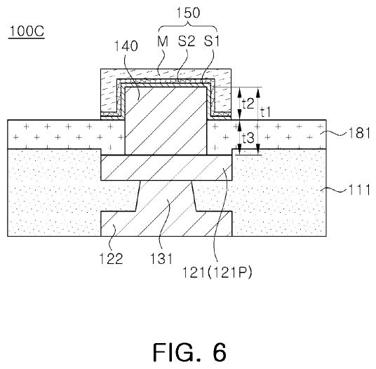

FIG. 6 is a schematic cross-sectional view of another example of a printed circuit board.

Referring to the drawings, a printed circuit board 100C according to another example embodiments may include a plurality of layers in which seed layers S1 and S2 of a second conductive bump 150 include different metals, as compared to the above-described printed circuit board 100A according to some example embodiments. For example, the seed layers S1 and S2 of the second conductive bump 150 may be formed of a plurality of layers including, in an order listed, a first layer S1 including titanium (Ti) and a second layer S2 including copper (Cu). For example, the seed layers S1 and S2 of the second conductive bump 150 may be formed through a sputtering process, or may be formed through a sputtering process and an electroless plating process. In the sputtering process, a titanium (Ti) film may be formed, or a titanium (Ti) film and a copper (Cu) film may be sequentially formed. In the electroless plating process, chemical copper may be formed. For example, the first layer S1 may include sputtered titanium (Ti). In addition, the second layer S2 may include sputtered copper (Cu), or may include both sputtered copper (Cu) and chemical copper. As described, when the first layer S1 including a metal different from copper (Cu), for example, titanium (Ti), is formed on a surface of the passivation layer 181, adhesion strength may be improved.

Other contents may be substantially the same as those described in connection with the above-described printed circuit board 100A according to an example. In addition, the contents described in connection with the above-described manufacturing example may also be applied to the printed circuit board 100B according to another example. In addition, the surface treatment layer 160 described in connection with the above-described printed circuit board 100B according to another example may also be applied to the printed circuit board 100C according to another example.

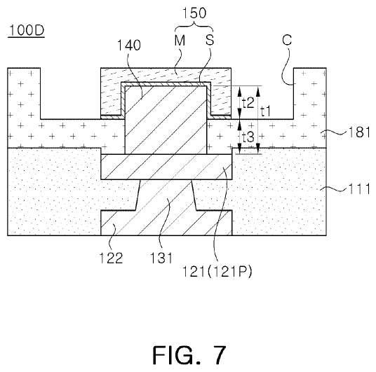

FIG. 7 is a schematic cross-sectional view of another example of a printed circuit board.

Referring to the drawings, in a printed circuit board 100D according to another example, a passivation layer 181 may have a blind cavity C, as compared to the above-described printed circuit board 100A according to some example embodiments. Accordingly, an upper surface of the passivation layer 181 may have a step portion due to the blind cavity C. For example, the passivation layer 181 may have a two-stage step structure. In this case, the above-described conductive pad 121P and first and second conductive bumps 140 and 150 may be disposed in a region overlapping the blind cavity C. Here, the region, overlapping the blind cavity C, may refer to a region disposed in the blind cavity C in a top view and/or side view. The blind cavity C may be formed, for example, by irradiating ultraviolet rays to an external region of the passivation layer 181, curing the external region, and etching a remaining uncured region of the passivation layer 181. In this case, an upper surface of the passivation layer 181 in a region in which the blind cavity C is formed may have a surface roughness, as described above. Conversely, an upper surface of the passivation layer 181 in a region in which the blind cavity C is not formed may have a smooth surface. For example, the upper surface of the passivation layer 181 in the region in which the blind cavity C is formed may have a surface roughness, relatively greater than that of the upper surface of the passivation layer 181 in the region in which the blind cavity C is not formed. As described above, a height of the passivation layer 181 may be selectively lowered only in a region in which a die is mounted, and a surface of the passivation layer 181 may have roughness. Accordingly, the die may be mounted more effectively in a packaging operation, and reliability may be enhanced.

Other contents may be substantially the same as those described in connection with the above-described printed circuit board 100A according to an example. In addition, the contents described in connection with the above-described manufacturing example may also be applied to the printed circuit board 100C according to another example. In addition, the surface treatment layer 160 described in connection with the printed circuit board 100B according to another example may also be applied to the printed circuit board 100C according to another example.

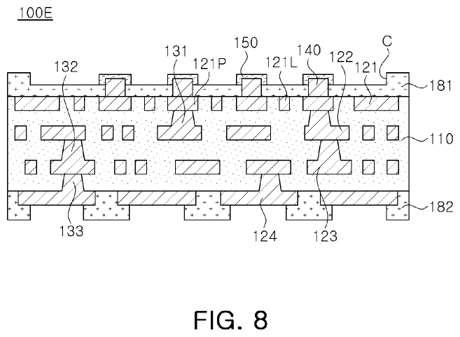

FIG. 8 is a schematic cross-sectional view of another example of a printed circuit board.

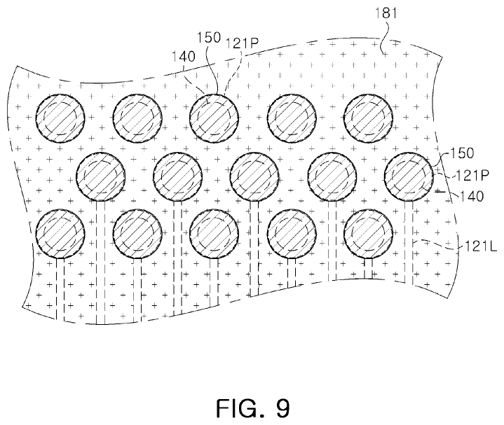

FIG. 9 is a schematic planar view of a top view of the printed circuit board of FIG. 8.

Referring to the drawings, a printed circuit board 100E according to another example embodiments may have a multilayer coreless substrate structure. For example, the printed circuit board 100E according to another example may include an insulating layer 110, a plurality of wiring layers 121, 122, 123 and 124 respectively disposed on or in the insulating layer 110, and a plurality of via layers 131, 132, and 133 respectively disposed in the insulating layer 110, the plurality of via layers 131, 132, and 133 connecting the plurality of wiring layers 121, 122, 123, and 124 to each other, a first passivation layer 181 disposed on an upper surface of the insulating layer 110, and a second passivation layer 182 disposed on a lower surface of the insulating layer 110. Among the plurality of wiring layers 121, 122, 123, and 124, an uppermost wiring layer 121 may be a buried pattern layer buried in an upper side of the insulating layer 110, and may include a conductive pad 121P and a conductive line 121L. The conductive pad 121P and the conductive line 121L may be provided as a plurality of conductive pads 121P and a plurality of conductive lines 121L, respectively, and first and second conductive bumps 140 and 150 may be disposed on each of the conductive pads 121P. Among the plurality of wiring layers 121, 122, 123 and 124, a lowermost wiring layer 124 may be a protruding pattern layer protruding onto the lower surface of the insulating layer 110. The first passivation layer 181 may have a blind cavity C. The second passivation layer 182 may have a plurality of openings, respectively exposing at least a portion of the lowermost wiring layer 124. The multilayer coreless substrate having such a structure may be used as a package substrate and/or an interposer substrate.

The plurality of conductive lines 121L may be connected to a portion of the plurality of conductive pads 121P. In addition, at least a portion of each of the plurality of conductive lines 121L may be disposed, in a planar view, between at least two conductive pads, among the plurality of conductive pads 121P. When the plurality of conductive lines 121L are disposed between the plurality of conductive pads 121P as described above, the risk may increase in a typical case due to various side effects, but in the case of the printed circuit board 100E according to another example, this risk may be eliminated by forming the first and second conductive bumps 140 and 150 on a plurality of conductive pads 121P, respectively.

The insulating layer 110 may include the above-described insulating layer 111, and details thereof may be substantially the same as those described in the above-described insulating layer 111. In addition, the plurality of wiring layers 121, 122, 123, and 124 may include the above-described wiring layers 121 and 122, and details thereof may be substantially the same as those described in connection with the above-described wiring layers 121 and 122. In addition, the plurality of via layers 131, 132, and 133 may include the above-described via layer 131, and details thereof may be substantially the same as those described in the above-described via layer 131. In addition, the passivation layers 181 and 182 may include the above-described passivation layer 181, and details thereof may be substantially the same as those described in connection with the above-described passivation layer 181.

The structure of the above-described printed circuit board 100A according to another example embodiments and the manufacturing thereof may be applied to the printed circuit board 100E according to another example embodiments. In addition, the structure of the above-described printed circuit board 100B according to another example may also be applied. In addition, the structure of the above-described printed circuit board 100C according to another example may also be applied. In addition, the structure of the above-described printed circuit board 100D according to another example may also be applied.

As used herein, the terms “cover,” “to cover,” and “covering” may include not only entirely covering but also at least partially covering, and may include not only directly covering but also indirectly covering. In addition, the terms “fill,” “to fill,” and “filling” may include not only entirely filling but also at least partially filling, and may also include approximately filling. For example, the terms may include a case in which some voids, pores or the like are present. In addition, the terms “surround,” “to surround,” and “surrounding” may include not only entirely surrounding but also partially surrounding, and may also include approximately surrounding. In addition, the terms “exposing” may include not only entirely exposing a structure but also exposing at least a portion of the structure, and the term “exposure” may mean exposing a component from another component in which the component is buried. For example, an opening, exposing a pad, may be exposing the pad from an outermost insulating layer, and a surface treatment layer or the like may be further disposed on the exposed pad.

As used herein, a process error or a positional deviation occurring in a manufacturing process, an error in measurement, and the like may be included. For example, “being disposed on substantially the same level” may include not only “being disposed in completely the same position” but also “being disposed in approximately the same position.” In addition, “having a substantially specific shape” may include not only “having a completely specific shape” but also “having an approximately specific shape.” For example, such determination may be based on an overall shape. In addition, the same insulating material may mean not only the exact same insulating material, but also the same type of insulating material. Thus, compositions of insulating materials may be substantially the same, but specific composition ratios thereof may slightly vary.

As used herein, “in cross-section” may refer to a cross-sectional shape of an object when the object is vertically cut, or a cross-sectional shape of the object when the object is viewed in a side-view. In addition, a shape in a planar view may be a shape of the object when the object is horizontally cut, or a planar shape of the object when the object is viewed in a top view or a bottom-view.

As used herein, an upper side, an upper portion, the upper surface, or the like is used to refer to a downward direction based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper” and “lower” may change at any time.

As used herein, the term “connected” may not only refer to “directly connected” but also “indirectly connected” by means of an adhesive layer or the like. The term “electrically connected” may include both a case in which components are “physically connected” and a case in which components are “not physically connected.” In addition, the terms “first,” “second,” and the like may be used to distinguish a component from another component, and may not imply any particular order and/or importance, or others in relation to the components. In some cases, a first component may be referred to as a second component, and similarly, a second component may be referred to as a first component without departing from the scope of the example embodiments.

As used herein, thickness, width, length, depth, line width, spacing, pitch, distance, and surface roughness may be measured using a scanning microscope or an optical microscope based on a cross-section obtained by polishing or cutting a printed circuit board. The cross-section may be a vertical cross-section or a horizontal cross-section, and each value may be measured based on a required cross-section. When values measured for the printed circuit board are not consistent, a value of the printed circuit board may be determined as an average value of values measured at arbitrary five points.

As used herein, the term “an example” does not mean the same example embodiment, and is provided to emphasize different unique features. However, the examples presented above do not preclude implementation in combination with features of other examples. For example, a specific feature is described in one example but not in another, it may still be understood as being applicable to the other example, unless there is an explicit contradiction or inconsistency with what is described in that other example.

The terms used herein describe particular examples only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
an insulating layer;
a conductive pad buried in an upper side of the insulating layer such that at least a portion of an upper surface of the conductive pad is exposed from an upper surface of the insulating layer;
a first conductive bump disposed on the upper surface of the conductive pad;
a passivation layer disposed on the upper surface of the insulating layer, the passivation layer covering: a portion of the upper surface of the conductive pad on which the first conductive bump is not disposed; and a portion of a side surface of the first conductive bump; and
a second conductive bump disposed on an upper surface of the passivation layer, the second conductive bump covering a portion of the side surface of the first conductive bump on which the passivation layer is not covered and an upper surface of the first conductive bump.

2. The printed circuit board of claim 1, wherein the insulating layer includes a photosensitive insulating material.

3. The printed circuit board of claim 1, wherein
a surface roughness of the upper surface of the passivation layer is greater than a surface roughness of a lower surface of the passivation layer, and
the second conductive bump is in contact with the upper surface of the passivation layer.

4. The printed circuit board of claim 1, wherein
the upper surface of the conductive pad is recessed below the upper surface of the insulating layer, and
the passivation layer fills at least a portion of the recessed space.

5. The printed circuit board of claim 4, wherein when a thickness from the upper surface of the conductive pad to the upper surface of the first conductive bump is denoted by t1, and a thickness from the upper surface of the passivation layer to the upper surface of the first conductive bump is denoted by t2, (t1*20%)<t2<(t1*80%) is satisfied.

6. The printed circuit board of claim 4, wherein when a thickness from the upper surface of the conductive pad to the upper surface of the first conductive bump is denoted by t1, and a thickness from the upper surface of the conductive pad to the upper surface of the passivation layer is denoted by t3, (t1*20%)<t3<(t1*80%) is satisfied.

7. The printed circuit board of claim 1, wherein the second conductive bump includes a seed layer substantially conformally and continuously covering the upper surface of the passivation layer, the other portion of the side surface of the first conductive bump, and the upper surface of the first conductive bump, and a pattern layer disposed on the seed layer.

8. The printed circuit board of claim 7, wherein each of the seed layer and the pattern layer includes a single layer including copper (Cu).

9. The printed circuit board of claim 7, wherein
the seed layer includes a plurality of layers including, in an order listed, a layer including titanium (Ti) and a layer including copper (Cu), and
the pattern layer includes a single layer including copper (Cu).

10. The printed circuit board of claim 1, further comprising:
a surface treatment layer covering an upper surface and a side surface of the second conductive bump.

11. The printed circuit board of claim 10, wherein the surface treatment layer includes a plurality of layers including, in this order, a layer including nickel (Ni) and a layer including gold (Au).

12. The printed circuit board of claim 1, wherein
the passivation layer has a blind cavity,
the upper surface of the passivation layer has a step portion due to the blind cavity, and
the conductive pad and the first and second conductive bumps are disposed in a region overlapping the blind cavity.

13. The printed circuit board of claim 12, wherein a surface roughness of the upper surface of the passivation layer in a region in which the blind cavity is disposed is greater than a surface roughness of the upper surface of the passivation layer in a region in which the blind cavity is not disposed.

14. The printed circuit board of claim 1, further comprising:
a plurality of wiring layers respectively disposed on or in the insulating layer; and
a plurality of via layers respectively disposed in the insulating layer, the plurality of via layers connecting the plurality of wiring layers to each other,
wherein an uppermost wiring layer, among the plurality of wiring layers, is buried in an upper side of the insulating layer,
a lowermost wiring layer, among the plurality of wiring layers, protrudes onto a lower surface of the insulating layer, and
the uppermost wiring layer includes the conductive pad.

15. The printed circuit board of claim 14, wherein
the conductive pad and the first and second conductive bumps are provided as a plurality of conductive pads and a plurality of first and second conductive bumps,
the uppermost wiring layer further includes a plurality of conductive lines,
the plurality of conductive lines are respectively connected to a portion of the plurality of conductive pads, and
at least a portion of each of the plurality of conductive lines is disposed, in a planar view, between at least two conductive pads, among the plurality of conductive pads.

16. A printed circuit board comprising:
a conductive pad;
a first conductive bump connected to an upper surface of the conductive pad;
a second conductive bump connected to an upper end of the first conductive bump;
an insulating layer in contact with at least a portion of the conductive pad, the insulating layer spaced apart from the first and second conductive bumps, the insulating layer including a photosensitive insulating material; and
a passivation layer disposed on an upper surface of the insulating layer, the passivation layer in contact with at least a portion of each of the conductive pad and the first and second conductive bumps,
wherein the upper end of the first conductive bump to which the second conductive bump is connected protrudes onto an upper surface of the passivation layer.

17. The printed circuit board according to claim 16, wherein the photosensitive insulating material includes an epoxy-based photosensitive polymer or an acryl-based photosensitive polymer.

18. The printed circuit board according to claim 17, wherein the photosensitive insulating material further includes a filler.
